(19) United States
(12) Patent Application Publication
(10) Pub. No.: US 2006/0220494 A1
(43) Pub. Date: Oct. 5, 2006

(54) Elastic boundary wave device, resonator, and ladder-type filter

(75) Inventors: Michio Miura, Kawasaki (JP); Takashi Matsuda, Kawasaki (JP); Masanori Ueda, Yokohama (JP); Seiichi Mitobe, Yokohama (JP)

Correspondence Address: ARENT FOX PLLC, 1050 CONNECTICUT AVENUE, N.W., SUITE 400, WASHINGTON, DC, 20036, US

(73) Assignees: FUJITSU MEDIA DEVICES LIMITED; FUJITSU LIMITED

(21) Appl. No.: 11/390,132

(22) Filed: Mar. 28, 2006

(30) Foreign Application Priority Data
Mar. 29, 2005 (JP) 2005-096518

(51) Int. Cl. H03H 9/25

(52) U.S. Cl. 310/313 D

(57) ABSTRACT

An elastic boundary wave device includes a first medium that is piezoelectric, electrodes provided on the first medium to excite elastic waves, a dielectric film provided on the electrodes and the first medium, and a second medium provided on the dielectric film. The dielectric film mainly includes silicon oxide and a density thereof is at least 2.05 g/cm³.

### BACKGROUND OF THE INVENTION

1. Field of the Invention

This invention generally relates to elastic boundary wave devices and resonators having the same and ladder-type filters having the same, and more particularly, to an elastic boundary wave device having an excellent temperature characteristic and a resonator having the same and a ladder-type filter having the same.

2. Description of the Related Art

Conventionally, surface acoustic wave devices (also known as SAW device) are well known as one of the devices that apply elastic waves. The SAW devices are used for various circuits that process wireless signals in the frequency band of 45 MHz to 2 GHz, which are typically used on mobile telephones. The various circuits include, for example, bandpass filters for transmission or reception, filter for local oscillation, antenna duplexer, IF filter, FM modulator, and the like. These years, there is a need for the improved temperature characteristic of the SAW device for use in, for example, a bandpass filter, along with high-performance of the mobile telephones. In addition, there is another need for the downsized device.

In order to improve the temperature characteristic, Japanese Patent Application Publication No. 2003-209458 discloses a surface acoustic wave device in which silicon oxide films having different signs of temperature characteristic are formed on a piezoelectric substrate. On the SAW device, the waves propagate on the surface thereof in concentration. If a foreign material is adhered to the surface of the substrate, there is a change or degradation in the characteristics such as a changed frequency or increased electric loss. Therefore, the SAW device is generally mounted on a hermetically sealed package. This makes it difficult to downsize the device and causes the increased production costs.

Masatsune Yamaguchi, Takashi Yamashita, Ken-ya Hashimoto, Tatsuya Omori, “Highly Piezoelectric Boundary Waves in Si/SiO₂/LiNbO₃ Structure”, Proceeding of 1998 IEEE International Frequency Control Symposium, (United States), IEEE, 1998, pp. 484-488, discloses a device that employs the boundary wave that travels on the boundary between different media, instead of the surface wave, in order to realize the improvement in the temperature characteristic, the downsizing of the device, and the reduction in the production costs. According to Yamaguchi et al., also discloses the boundary waves that travel on a 0 degree-rotation Y-plane LiNbO₃ substrate, on a LN substrate, and on a structure where a silicon oxide film and a silicon film are deposited, on the basis of the calculation results.

Yamaguchi et al., however, suggests the possibility of elastic boundary wave having an excellent temperature characteristic, yet does not disclose a method for realizing the elastic boundary wave device concretely.

### SUMMARY OF THE INVENTION

The present invention has been made in view of the above circumstances and provides an elastic boundary wave device having an excellent temperature characteristic, a resonator having the same, and a ladder-type filter having the same.

According to one aspect of the present invention, preferably, there is provided an elastic boundary wave device including: a first medium that is piezoelectric; excitation electrodes provided on the first medium to excite elastic waves; a dielectric film provided on the excitation electrodes and the first medium; and a second medium provided on the dielectric film. The dielectric film mainly includes silicon oxide and a density thereof is at least 2.05 g/cm³. In accordance with the present invention, it is possible to provide the elastic boundary wave device having an excellent temperature characteristic, by employing the silicon oxide film having an opposite code of the temperature coefficient from that of the first medium for the dielectric film.

According to another aspect of the present invention, preferably, there is provided a resonator including: a first medium that is piezoelectric; excitation electrodes provided on the first medium to excite elastic boundary waves and reflector electrodes provided on the first medium; a dielectric film provided on the excitation electrodes, the reflector electrodes and the first medium; and a second medium provided on the dielectric film. The dielectric film mainly includes silicon oxide and a density thereof is at least 2.05 g/cm³.

According to another aspect of the present invention, preferably, there is provided a ladder-type filter including: a first medium that is piezoelectric; excitation electrodes provided on the first medium to excite elastic boundary waves and reflector electrodes provided on the first medium, resonators including the excitation electrodes and the reflector electrodes being arranged in a ladder form; a dielectric film provided on the excitation and reflection electrodes and the first medium; and a second medium provided on the dielectric film. The dielectric film mainly includes silicon oxide and a density thereof is at least 2.05 g/cm³.

### BRIEF DESCRIPTION OF THE DRAWINGS

Preferred embodiments of the present invention will be described in detail with reference to the following drawings, wherein:

FIG. 1 is a cross-sectional view of an elastic boundary wave device in accordance with a first embodiment of the present invention;

FIG. 2 shows calculation results of TCV (Temperature Coefficient of Velocity) of the elastic boundary wave device in accordance with the first embodiment of the present invention with respect to SiO₂ thickness (h/λ);

FIG. 3 shows measurement results of TCF (Temperature Coefficient of Frequency) of the elastic boundary wave device in accordance with the first embodiment of the present invention with respect to the SiO₂ thickness h/λ;

FIG. 4 shows TCF with respect to a LT orientation (Y-rotation angle) in the elastic boundary wave device in accordance with the first embodiment of the present invention;

FIG. 5 is a cross-sectional view of an elastic boundary wave device in accordance with a second embodiment of the present invention;

FIG. 6 shows attenuation amount of the elastic boundary wave device in accordance with the second embodiment with respect to the frequency;

FIG. 7 is a top view of a resonator in accordance with a third embodiment of the present invention;

FIG. 8 is a top view showing a ladder-type filter in accordance with a fourth embodiment of the present invention; and

FIG. 9 is another top view showing the ladder-type filter in accordance with the fourth embodiment of the present invention.

### DESCRIPTION OF THE PREFERRED EMBODIMENTS

A description will now be given, with reference to the accompanying drawings, of embodiments of the present invention.

### First Embodiment

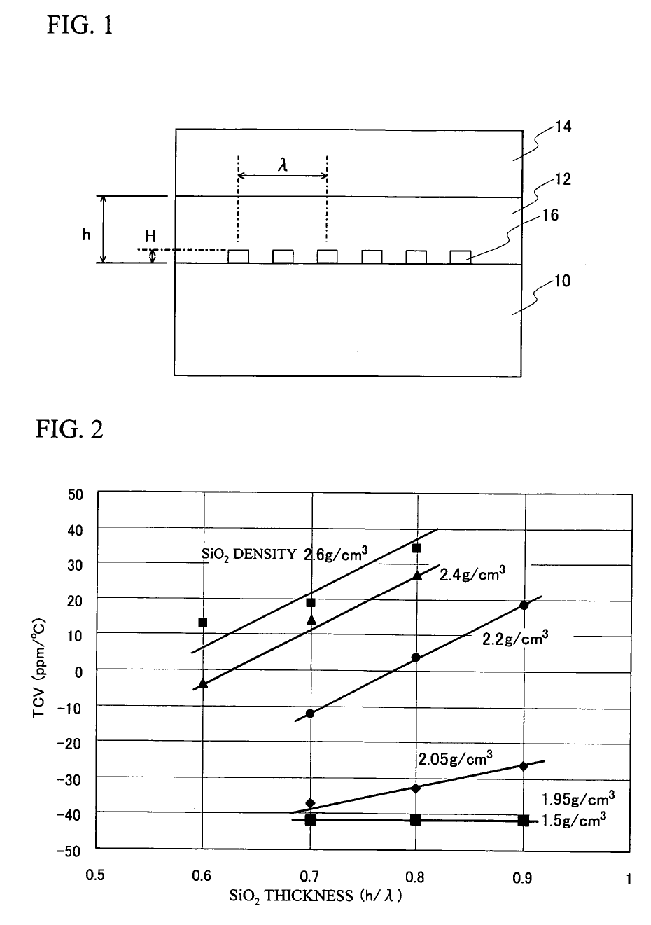

FIG. 1 is a cross-sectional view of an elastic boundary wave device in accordance with a first embodiment of the present invention. Excitation electrodes 16 that excite elastic waves are provided on a first medium 10 that is piezoelectric, and a dielectric film 12 and a second medium 14 are provided thereon. The electrodes 16 excite, for example, the boundary waves, which are the elastic waves, and are comb-like electrodes. Here, h denotes a film thickness of the dielectric film 12, H denotes a film thickness of the comb-like electrode 16, and λ denotes a period of the comb-like electrode 16. In accordance with the first embodiment of the present invention, the first medium 10 employs a LiTaO₃ (hereinafter, simply referred to as LT) substrate of 42 degrees rotation, Y-plate, the electrode 16 is a comb-like electrode that mainly includes copper, the dielectric film 12 employs a silicon oxide film (a film that mainly includes silicon oxide), and the second medium 14 employs silicon.

Here, an X-axis direction of the LT substrate of 42 degrees rotation, Y-plate is a horizontal direction in FIG. 1, namely, a propagation direction of the boundary wave. In accordance with the first embodiment, the boundary wave travels along the boundary between the first medium 10 and the dielectric film 12. Therefore, even if a foreign material is adhered to the surface of the second medium 14, there is neither change nor degradation in characteristics such as the changed frequency, the increased electric loss, or the like, unlike the device that utilizes the surface wave. Accordingly, elastic boundary wave device in accordance with the first embodiment of the present invention needs not to be mounted on a hermetically sealed package. The device that utilizes the elastic boundary wave can be readily downsized and the production costs can be reduced.

FIG. 2 shows calculation results, with use of the finite element method, of temperature coefficient of velocity (TCV: Temperature Coefficient of Velocity) of the boundary wave with respect to h/λ, which corresponds to the film thickness of the silicon oxide film in the elastic boundary wave device in accordance with the first embodiment of the present invention. As TCV is closer to 0, the temperature dependency of the boundary wave on the velocity is small and the temperature characteristics are excellent. FIG. 2 shows a case where the density of the silicon oxide film (SiO₂ density) of the dielectric film 12 is changed from 1.5 g/cm³ to 2.6 g/cm³.

If the density of the silicon oxide film (SiO₂ density) is less than 2.05 g/cm³, the slope of TCV to h/λ is extremely small. Even if h/λ is changed in a case where the density of the silicon oxide film (SiO₂ density) is less than 2.05 g/cm³, TCV is not close to 0. In this state, an elastic boundary wave device having an excellent temperature characteristic is not obtainable. In contrast, if the density of the silicon oxide film (SiO₂ density) is 2.05 g/cm³ or more, TCV can be made close to 0 by changing h/λ. For example, if the densities of the silicon oxide film (SiO₂ density) are respectively 2.2 g/cm³, 2.4 g/cm³, and 2.62 g/cm³, and h/λ are respectively 0.8, 0.7, and 0.6. TCV can be made close to 0. In this manner, it is possible to provide the elastic boundary wave device having an excellent temperature characteristic.

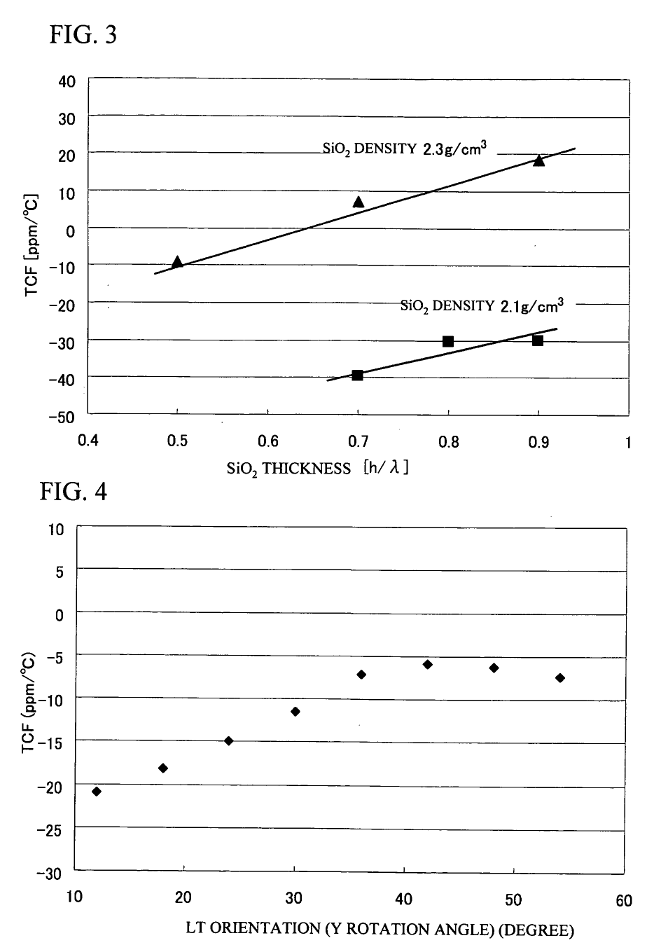

FIG. 3 shows measurement results of temperature coefficient of frequency (TCF: Temperature Coefficient of Frequency) of the elastic boundary wave device with respect to h/λ, which corresponds to the film thickness of silicon oxide film (SiO₂ thickness) in the elastic boundary wave device in accordance with the first embodiment of the present invention. FIG. 3 shows a case where the density of the silicon oxide film (SiO₂ density) of the dielectric film 12 is changed from 2.1 g/cm³ to 2.3 g/cm³. FIG. 3 shows the results of TCF, because it is difficult to measure TCV. As TCF is closer to 0, the temperature characteristic of frequency of the elastic boundary wave device is excellent, as seen in TCV. It is preferable that TCF should be 0±10 ppm/° C. in order to obtain an elastic boundary wave device having an excellent temperature characteristic. As shown in FIG. 3, even if h/λ is changed in a case where the density of the silicon oxide film (SiO₂ density) is 2.1 g/cm³ or less, TCF is not close to 0. In contrast, by setting h/λ to 0.6 in a case where the density of the silicon oxide film (SiO₂ density) is 2.3 g/cm³, TCF becomes closer to 0. This makes it possible to provide an elastic boundary wave device having an excellent temperature characteristic.

Hereinafter, the results shown in FIG. 2 and FIG. 3 are summarized. TCF of the elastic surface wave device with the use of LT substrate, namely, the device that does not include a dielectric film, is approximately −40 ppm/° C. In both FIG. 2 and FIG. 3, even if h/λ is made greater in a case where the density of the silicon oxide film is less than 2.05 g/cm³, TCV is −40 ppm/° C., which is not largely different from the temperature characteristic of the LT substrate. This exhibits that if the density of the silicon oxide film is small, which does not influence the temperature characteristic of the boundary wave. In contrast, the density of the silicon oxide film is 2.05 g/cm³ or more, there is an opposite temperature characteristic with respect to the LT substrate. Accordingly, TCF is made greater by increasing the thickness of the silicon oxide film. It is therefore possible to provide the elastic boundary wave device having a small temperature characteristic by optimizing the thickness of the silicon oxide film.

As described above, the elastic boundary wave device having an excellent temperature characteristic can be provided by setting the density of the silicon oxide film that composes the dielectric film 12 to 2.05 g/cm³ or more and optimizing h/λ.

As a method for increasing the density of the silicon oxide film of the dielectric film 12, for instance, there is a method that the silicon oxide film includes nitrogen. This makes a silicon oxide nitride film having an increased density. Nitrogen can be readily included in a normally employed method such as sputtering or CVD. The density of the silicon oxide film may be greater by changing the film forming condition of sputtering or CVD.

FIG. 4 shows TCF with respect to the orientation of the LT substrate in the elastic boundary wave device having a same configuration with that in accordance with the first embodiment of the present invention. Here, h/λ of the silicon oxide film is 0.5. In the LT orientation that ranges form 10 to 55 degrees, TCF of the elastic boundary wave device is −20 ppm/° C. to −5 ppm/° C. As described above, TCF of the elastic surface wave device that does not include the silicon oxide film is approximately −40 ppm/° C. This explains that TCF can be improved by employing the silicon oxide film for the dielectric film 12, even if the LT orientation is changed. In addition, as described, it is necessary to set the density of the silicon oxide film to 2.05 g/cm³ or more in order to influence the temperature characteristic of the boundary wave. The density of the silicon oxide film that influences the temperature characteristic of the boundary wave, which is 2.05 g/cm³ or more, is determined by the temperature characteristic of the silicon oxide film and that of the LT substrate. Accordingly, for example, if the silicon oxide film having the density of 2.05 g/cm³ or more is employed and h/λ is optimized in a case where the substrate of LT orientation is used for the first medium 10 except the LT substrate of the 42 degrees, Y-axis rotation, it is possible to provide an elastic boundary wave device having an excellent temperature characteristic.

If the silicon oxide film is formed on the comb-like electrode 16 as the dielectric film 12, a hollow is sometimes generated between the comb-like electrodes 16. In order to suppress the generation of such hollow, it is effective that a film thickness H of the comb-like electrode is made thin so that unevenness of the surface is reduced when the silicon oxide film is formed. However, as the film thickness of the comb-like electrode 16 is thinner, the mass of the comb-like electrode becomes lighter. This results in a decrease in the reflectance of the boundary wave on the comb-like electrode 16. This does not confine the boundary wave very well, causing the high-frequency loss. In addition, if the film thickness of the comb-like electrode 16 is reduced, the electric resistance is increased, making the high-frequency loss greater. Therefore, when the film of the comb-like electrode 16 is made thin, it is preferable that the comb-like electrode 16 should include, for example, copper or gold, both of which are high in density and low in resistance. This is the reason the comb-like electrode 16 employs a metal that mainly includes copper in accordance with the first embodiment of the present invention. In this manner, it is possible to suppress the high-frequency loss without a hollow, by employing the metal that mainly includes copper or gold.

For instance, the silicon oxide film may be formed without a hollow by optimizing the film making condition of the silicon oxide film by sputtering or CVD, or improving a film making apparatus. In this case, even a metal having a relatively light density such as aluminum or the like may be used for the comb-like electrode 16. In addition, the boundary wave travels between the first medium 10 and the dielectric film 12. Therefore, even if the copper used for the comb-like electrode 16 in accordance with the first embodiment is changed to another material except copper, it is possible to provide the elastic boundary wave device having an excellent temperature characteristic by setting the density of the silicon oxide film of the dielectric film 12 to 2.05 g/cm³ or more. Furthermore, the comb-like electrode has been exemplarily described in the first embodiment of the present invention. However, any electrode other than the comb-like one may be employed, if the electrode excites the boundary wave.

Preferably, the second medium 14 has a sound velocity faster than that of the dielectric film 12. This is because the energy of the boundary wave is confined in the dielectric film 12. As a result, the high-frequency loss becomes smaller. It is preferable that the second medium 14 should be made of silicon, silicon nitride, aluminum nitride, or aluminum oxide, which have the velocities faster than that of the silicon oxide film. In accordance with the first embodiment of the present invention, silicon is used for the second medium 14. This is because it is easy to process silicon and easy to form a connection window that establishes an electric connection with an electrode pad. However, silicon is not an insulator, and dielectric loss is generated to cause the high-frequency loss. Preferably, the second medium 14 employs a material that mainly includes an insulator having the sound velocity faster than that of the dielectric film 12. More preferably, the second medium 14 employs silicon nitride, aluminum nitride, aluminum oxide, or a material that has an excellent crystal structure and mainly includes highly resistant silicon, in light of ease in film making and processing. The boundary wave travels between the first medium 10 and the dielectric film 12. Therefore, even if the second medium 14 is changed in the above-mentioned range, it is possible to provide the elastic boundary wave device having an excellent temperature characteristic by setting the density of the silicon oxide film of the dielectric film 12 to 2.05 g/cm³ or more.

As described heretofore, in accordance with the first embodiment of the present invention, it is possible to provide the elastic boundary wave device having an excellent temperature characteristic by employing a film that mainly includes silicon oxide for the dielectric film 12 and setting the density thereof to 2.05 g/cm³ or more.

### Second Embodiment

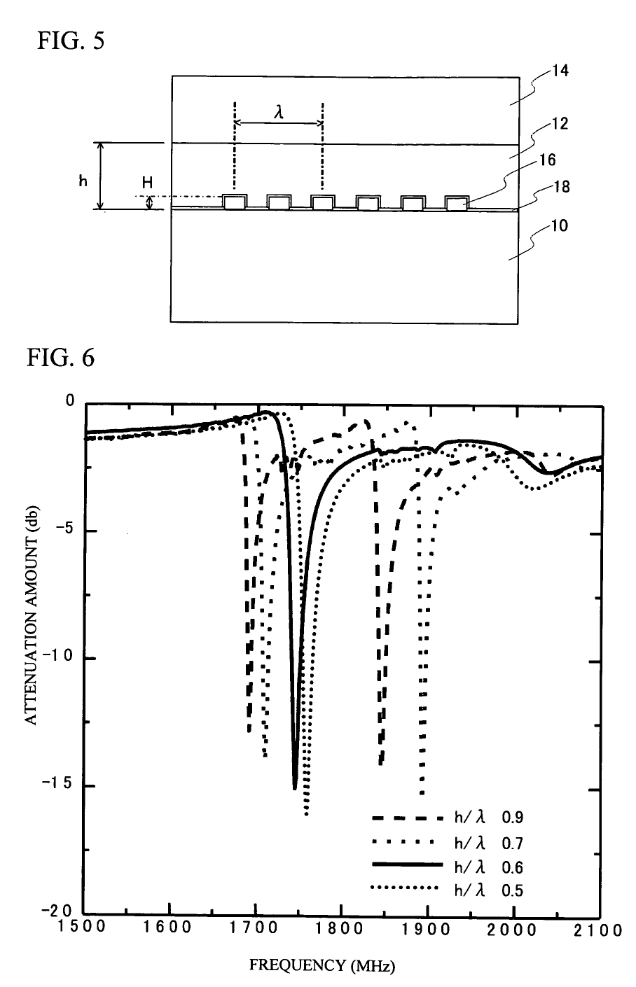

FIG. 5 is a cross-sectional view of an elastic boundary wave device in accordance with a second embodiment of the present invention. The elastic boundary wave device in accordance with the second embodiment has the same configuration as that in accordance with the first embodiment, except that aluminum oxide is employed for the second medium 14 and a barrier layer 18 is included between the electrodes 16 that excite the elastic waves and the dielectric film 12. That is to say, the first medium 10 is a LT substrate of 42 degrees rotation, Y-plate, the electrodes 16 that excite the elastic waves are comb-like electrodes that mainly include copper, the dielectric film 12 is a silicon oxide film, and the barrier layer is a silicon nitride film. Aluminum oxide is employed for the second medium 14, because it is easy to suppress the dielectric loss and easy to form and process the film for the second medium 14.

The barrier layer 18 is provided between the comb-like electrodes 16 and the dielectric film 12. The reasons are described. If the metal that mainly includes copper is used for the comb-like electrodes 16 in order to prevent the high-frequency loss as described, copper sometimes diffuses in the dielectric film 12. Therefore, the barrier layer 18 is provided for preventing the copper from diffusing into the dielectric film 12 that includes silicon oxide. It is only necessary that the barrier layer 18 should prevent the copper diffusion. In accordance with the second embodiment of the present invention, employed film is the silicon nitride film that functions as a barrier layer, serves as an insulating film, and is easily formed. The silicon nitride film can be formed by an identical film forming apparatus continuously with the dielectric film 12, and has an advantage that the burden is low in the manufacturing process.

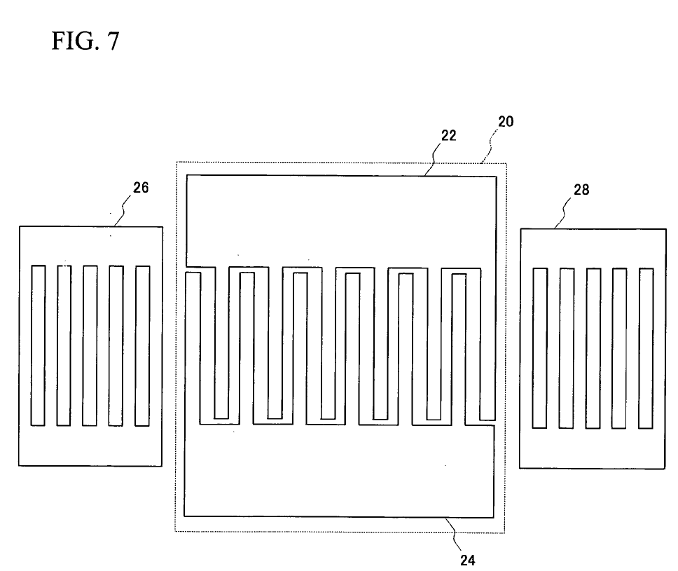

FIG. 6 shows attenuation amount of the elastic boundary wave device in accordance with the second embodiment with respect to the frequency. FIG. 6 shows the results when the period λ of the comb-like electrode 16 is set to 2 μm, and h/λ, namely, a ratio of the film thickness h of the dielectric film 12 to the period λ is changed from 0.5 to 0.9. When h/λ is 0.7 and 0.9, there are responses of attenuation amount in two frequency bands, approximately 1700 MHz and approximately 1900 MHz. On the other hand, when h/λ is 0.5 and 0.6, there in only one response of attenuation amount in approximately 1750 MHz. The response that ranges from 1700 MHz to 1750 MHz is a response of the boundary wave. When h/λ is 0.7 and 0.9, there is a response in approximately 1900 MHz. However, the cause of the response is not clear, yet is considered as a response of the surface wave, for example.

It is not desirable that there are responses in multiple frequency bands when the elastic boundary wave device is used as a ladder-type filter, for example. Preferably, h/λ is set to less than 0.7 to obtain a response in only one frequency band. More preferably, h/λ is set to 0.6 or less to certainly obtain a response in only one frequency band. Further preferably, h/λ is set to 0.5 or less to certainly obtain a response in only one frequency band.

In accordance with the second embodiment of the present invention, the barrier layer 18 is provided. The film thickness of the barrier layer 18 is thinner than that of the dielectric film 12, and so this does not largely influence the characteristics of the boundary wave. Accordingly, even in the elastic boundary wave device that does not include the barrier layer 18, it is possible to obtain the response in only one frequency band by setting h/λ to less than 0.7. Further, the boundary wave propagates between the first medium 10 and the dielectric film 12. Therefore, it is possible to obtain the response in only one frequency band by setting h/λ to less than 0.7, even if the second medium 14 employs a material other than aluminum oxide, such as silicon, silicon nitride, or aluminum nitride.

The barrier layer 18 is thin and the influence on the boundary wave is small. Therefore, the effects are obtainable in the second embodiment of the present invention, as in the first embodiment. That is to say, the film that mainly includes silicon oxide is employed for the dielectric film 12 and the density thereof is set to 2.05 g/cm³ or more, so that the elastic boundary wave device having an excellent temperature characteristic can be provided. In addition, it is possible to prevent copper from diffusing into the dielectric film 12 by forming the barrier layer 18, even if the metal that mainly includes copper is employed for the comb-like electrode 16.

### Third Embodiment

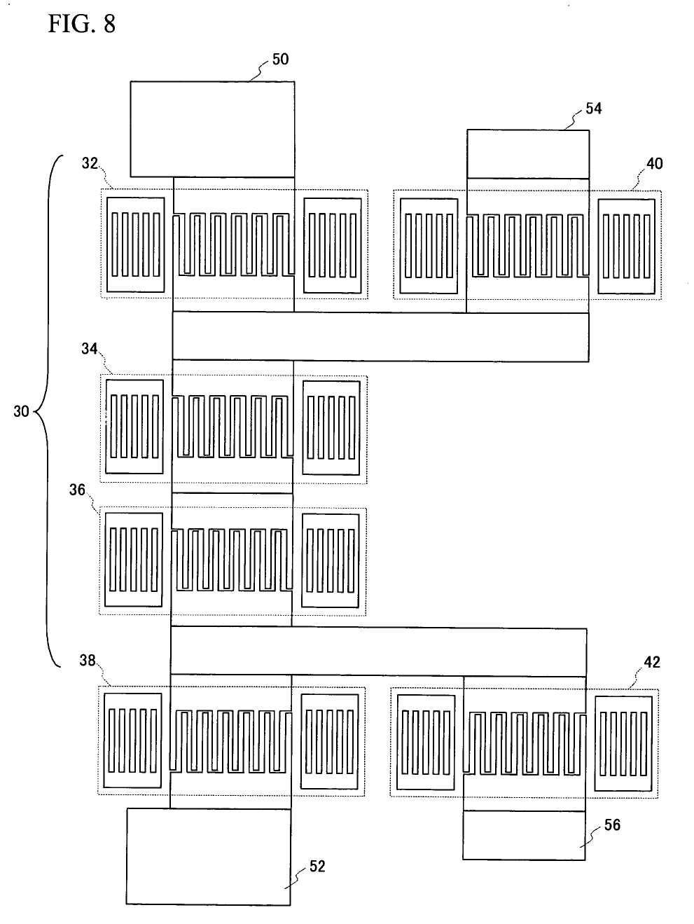

A third embodiment of the present invention exemplarily describes a resonator having the elastic boundary wave device in accordance with the second embodiment of the present invention. FIG. 7 is a top view of the resonator in accordance with the third embodiment of the present invention, yet does not show the second medium 14, the dielectric film 12, or the barrier layer. Reflectors 26 and 28 are arranged on both sides of an elastic boundary wave device 20 having comb-like electrodes. The elastic boundary wave device 20 has an input electrode 22 and an output electrode 24. The reflectors 26 and 28 are formed simultaneously with the elastic boundary wave device 20 having the comb-like electrodes. That is to say, the elastic boundary wave device 20 and the reflectors 26 and 28 are common in the first medium, the electrodes, the barrier layer, the dielectric film, and the second medium. The boundary wave that propagates to both sides from the elastic boundary wave device 20 is reflected by the reflectors 26 and 28. Such reflected boundary wave is a standing wave of the boundary wave inside the elastic boundary wave device 20. A resonator functions in this manner. In accordance with the third embodiment of the present invention, it is possible to provide the resonator having an excellent temperature characteristic by utilizing the elastic boundary wave device in accordance with the second embodiment of the present invention.

### Fourth Embodiment

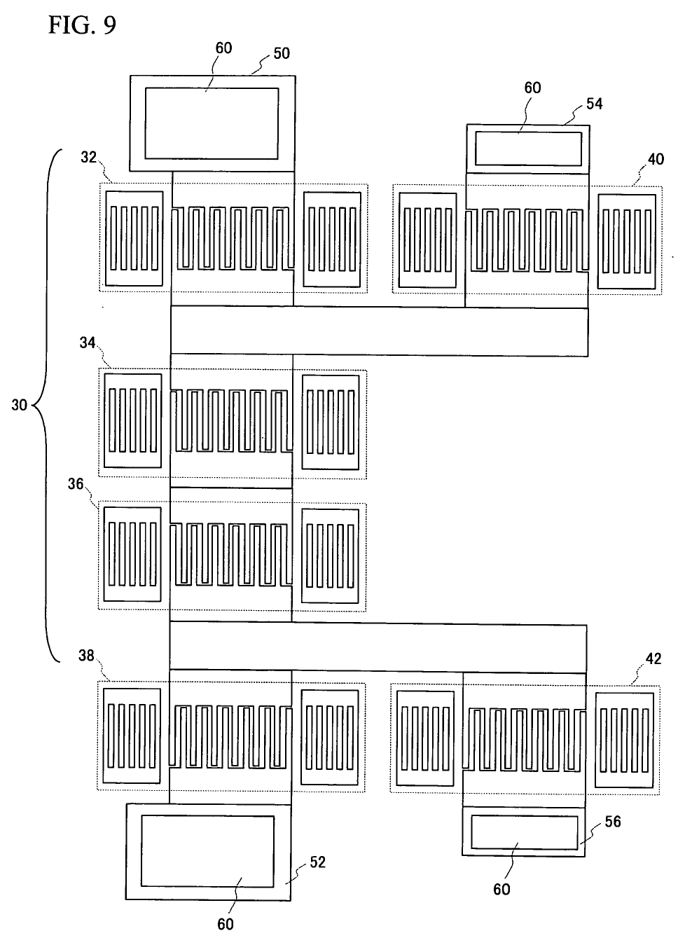

A fourth embodiment of the present invention exemplarily describes a ladder-type filter having four stages that includes the resonators in accordance with the third embodiment of the present invention. FIG. 8 is a top view showing a ladder-type filter in accordance with the fourth embodiment of the present invention, yet does not show the second medium 14, the dielectric film 12, or the barrier layer. As series-arm resonators 30, the resonators 32, 34, 36, and 38 in accordance with the third embodiment of the present invention are connected in series. One end of the resonator 32 is connected to an input pad electrode 50, and one end of the resonator 38 is connected to an output pad electrode 52. An electrode by which the resonator 38 and the resonator 36 are connected is connected to a resonator 40, and an electrode by which the resonator 38 and the resonator 36 are connected is connected to a resonator 42. The other ends of the resonator 40 and the resonator 42, which are not connected by, are respectively connected to ground pad electrodes 54 and 56. The resonators 40 and 42 respectively serve as a parallel-arm resonator. In accordance with the fourth embodiment of the present invention, the ladder-type filter functions in this manner.

The dielectric film 12 and the second medium 14 are formed on the electrodes of the elastic boundary wave device. In order to make an electric connection with the pad electrodes of the ladder-type filter, it is preferable that a connection window 60 should be provided in the second medium 14 formed on the pad electrodes. FIG. 9 shows the ladder-type filter shown in FIG. 8 having the afore-described windows 60 in the second medium 14. The connection windows 60 are provided on the output pad electrode 52 and the ground pad electrodes 54 and 56. Preferably, the connection window 60 should be provided in the dielectric film 12 and in the barrier layer 18, in addition to those in the second medium 14.

As described, in accordance with the fourth embodiment of the present invention, it is possible to provide the ladder-type filter having an excellent temperature characteristic by utilizing the resonator in accordance with the third embodiment of the present invention. In addition, the connection windows in the second medium provided on the pad electrode facilitates the electric connection.

In the elastic boundary wave device, the second medium may mainly include an insulator having a sound velocity faster than that of silicon oxide. Therefore, it is possible to confine the boundary wave in the dielectric film. The insulator is capable of suppressing the induction loss.

As used herein, “mainly include” denotes that a material is included within a scope of the effects described herein, even if another material is included.

The present invention is not limited to the above-mentioned embodiments, and other embodiments, variations and modifications may be made without departing from the scope of the present invention.

The present invention is based on Japanese Patent Application No. 2005-096518 filed on Mar. 29, 2005, the entire disclosure of which is hereby incorporated by reference.

What is claimed is:

1. An elastic boundary wave device comprising:
a first medium that is piezoelectric;
excitation electrodes provided on the first medium to excite elastic waves;
a dielectric film provided on the excitation electrodes and the first medium; and
a second medium provided on the dielectric film,
wherein the dielectric film mainly includes silicon oxide and a density thereof is at least 2.05 g/cm³.

2. The elastic boundary wave device as claimed in claim 1, wherein h/λ0 is smaller than 0.7, where h is a film thickness of the dielectric film and λ is a period of the excitation electrodes.

3. The elastic boundary wave device as claimed in claim 1, wherein the excitation electrodes mainly include either gold or copper.

4. The elastic boundary wave device as claimed in claim 1, further comprising a barrier layer provided between the excitation electrodes and the dielectric film.

5. The elastic boundary wave device as claimed in claim 1, wherein the dielectric film includes nitrogen.

6. The elastic boundary wave device as claimed in claim 1, wherein the dielectric film is formed by sputtering or CVD.

7. The elastic boundary wave device as claimed in claim 1, wherein the second medium mainly includes silicon.

8. The elastic boundary wave device as claimed in claim 1, wherein the second medium mainly includes an insulator having a sound velocity faster than that of silicon oxide.

9. The elastic boundary wave device as claimed in claim 8, wherein the second medium mainly includes at least one of silicon nitride, aluminum nitride, and aluminum oxide.

10. The elastic boundary wave device as claimed in claim 1, wherein a connection window is provided in the second medium on a pad electrode.

11. A resonator comprising:
a first medium that is piezoelectric;
excitation electrodes provided on the first medium to excite elastic boundary waves and reflector electrodes provided on the first medium;
a dielectric film provided on the excitation electrodes, the reflector electrodes and the first medium; and
a second medium provided on the dielectric film,
wherein the dielectric film mainly includes silicon oxide and a density thereof is at least 2.05 g/cm³.

12. A ladder-type filter comprising:
a first medium that is piezoelectric;
excitation electrodes provided on the first medium to excite elastic waves and reflector electrodes provided on the first medium, resonators including the excitation electrodes and the reflector electrodes being arranged in a ladder form;
a dielectric film provided on the excitation and reflection electrodes and the first medium; and
a second medium provided on the dielectric film,
wherein the dielectric film mainly includes silicon oxide and a density thereof is at least 2.05 g/cm³.
